(19) United States
(12) Patent Application Publication
(10) Pub. No.: US 2023/0163243 A1
(43) Pub. Date: May 25, 2023

(54) LIGHT-EMITTING DEVICE AND METHOD FOR MANUFACTURING THE SAME

(71) Applicant: QUANZHOU SANAN SEMICONDUCTOR TECHNOLOGY CO., LTD., Fujian (CN)

(72) Inventors: Tsung-Ming Lin, Fujian (CN); Yi-Jui Huang, Fujian (CN); Chung-Ying Chang, Fujian (CN); Yu-Tsai Teng, Fujian (CN)

(21) Appl. No.: 18/094,901

(22) Filed: Jan. 9, 2023

Related U.S. Application Data
(63) Continuation-in-part of application No. PCT/CN2020/141547, filed on Dec. 30, 2020.

(51) Int. Cl. H01L 33/22; H01L 33/00

(52) U.S. Cl. CPC H01L 33/22; H01L 33/005

(57) ABSTRACT

A light-emitting device includes a substrate that has a first surface and a second surface opposite to the first surface. The substrate has a thickness that is smaller than 80 µm, and the second surface has a roughened structure thereon with a surface roughness ranging from 0.5 µm to 1 µm. The light-emitting device further includes a chip unit that is disposed on the first surface of the substrate. A method for manufacturing the light-emitting device includes the steps of: providing an LED wafer that has a substrate and at least one chip unit, the substrate having a first surface and a second surface that is opposite to the first surface, the at least one chip unit being disposed on the first surface of the substrate; and laser processing the substrate for thinning the substrate and forming a roughened structure on the second surface of the substrate.

### CROSS-REFERENCE TO RELATED APPLICATION

This application is a continuation-in-part (CIP) of International Application No. PCT/CN2020/141547, filed on Dec. 30, 2020.

### FIELD

The disclosure relates to a light-emitting device and a manufacturing method thereof.

### BACKGROUND

The size of a mini light-emitting diode (mini LED) device is generally smaller than 5 mil*9 mil. Compared to a conventional light-emitting diode (LED) product, the mini LED device is more miniaturized in terms of size. Compared to the conventional LED device, a backlight that adopts the mini LED device provides more subtlety in lighting, offering high contrast, uniform brightness and excellent colors. When being used in a display, the mini LED device may further shorten distance among light-emitting diodes, thereby enhancing resolution of the display and improving the visual effect thereof.

Miniaturization of the mini LED device is required for reduction of light blocking at a seam of a splicing screen, so as to enhance the displaying effect. Therefore, requirement for making the mini LED device thinner has increased and thinning a substrate of the mini LED device has become an issue to be resolved.

Currently, chemical mechanical polishing (CMP) is used to thin a substrate in an LED wafer of the mini LED device. However, due to the stress between the substrate and an epitaxial structure of the LED wafer, when the LED wafer is disposed on a wafer support substrate and the substrate is ground to reduce the thickness thereof to below 80 µm, the LED wafer tends to warp significantly, causing edges of the LED wafer to chip and crack. As a result, the mini LED device may break easily, which leads to a low production yield rate.

Current technology has not offered an effective solution for reducing the thickness of the substrate to be smaller than 80 µm. Therefore, developing an ultra-thin mini LED device becomes an issue to be resolved.

### SUMMARY

Therefore, an object of the disclosure is to provide a light-emitting device that can alleviate at least one of the drawbacks of the prior art.

According to a first aspect of the disclosure, the light-emitting device includes a substrate that has a first surface and a second surface opposite to the first surface. The substrate has a thickness that is smaller than 80 µm, and the second surface has a roughened structure thereon with a surface roughness ranging from 0.5 µm to 1 µm. The light-emitting device further includes a chip unit that is disposed on the first surface of the substrate.

According to a second aspect of the disclosure, a method for manufacturing a light-emitting device includes the steps of: (S1) providing an LED wafer that has a substrate and at least one chip unit, the substrate having a first surface and a second surface that is opposite to the first surface, the at least one chip unit being disposed on the first surface of the substrate; and (S2) laser processing the substrate for thinning the substrate and forming a roughened structure on the second surface of the substrate.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a flow chart illustrating a method of manufacturing a light-emitting device according to a first embodiment of the disclosure.

FIG. 2 is a cross-sectional schematic view illustrating a substrate and an epitaxial structure disposed on the substrate in the first embodiment.

FIG. 3 is a cross-sectional schematic view illustrating an LED wafer that is formed after electrodes are disposed on the epitaxial structure.

FIG. 4 is a cross-sectional schematic view illustrating the substrate with a surface structure formed after laser processing to thin the substrate according to the first embodiment.

FIG. 5 is an AFM image diagram illustrating an AFM image of a second surface of the substrate after laser processing according to the first embodiment.

FIG. 6 is a cross-sectional schematic diagram illustrating the substrate with the surface structure formed after stealth dicing according to the first embodiment.

FIG. 7 is a cross-sectional schematic view illustrating a single light-emitting device obtained after laser cutting according to the first embodiment.

FIG. 8 is a cross-sectional schematic view illustrating a gallium arsenide substrate and the epitaxial structure grown thereon in a third embodiment of the disclosure.

FIG. 9 is a cross-sectional schematic view illustrating the epitaxial structure bonded to a sapphire substrate after being removed from the gallium arsenide substrate in the third embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

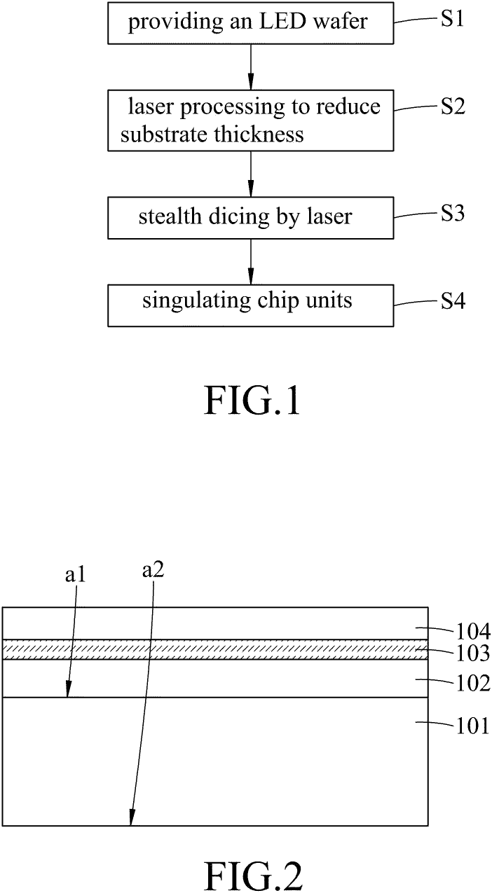

Referring to FIG. 1, a method for manufacturing a light-emitting device of the present disclosure includes the following steps.

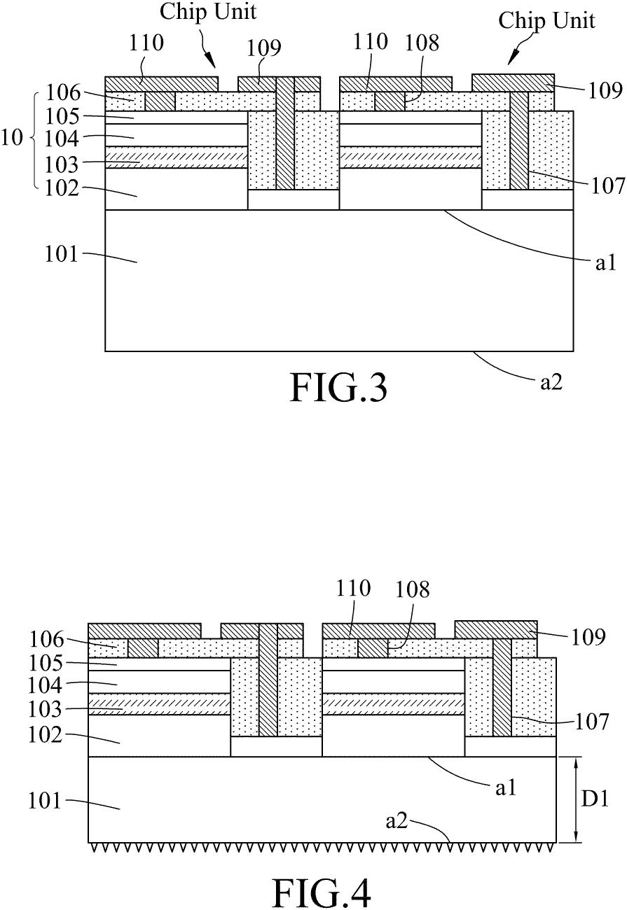

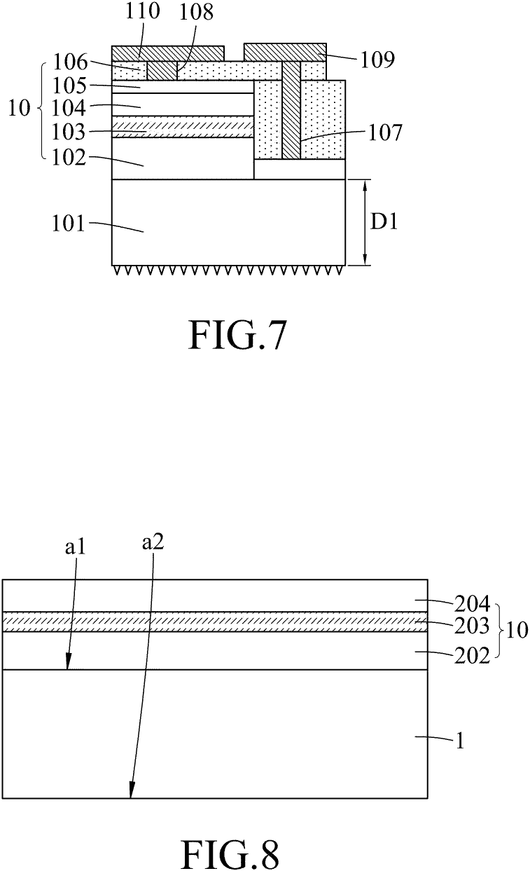

In step S1, an LED wafer is provided. The LED wafer includes a substrate (shown as 101 in FIGS. 2 and 3) and at least one chip unit (see FIGS. 3 and 7). In particular, a plurality of the chip units are disposed on the substrate. Each of the chip units includes an epitaxial structure (shown as 10 in FIG. 3) and electrodes that are disposed on the epitaxial structure 10.

The substrate 101 may be an insulating substrate or a conductive substrate. The substrate 101 may be a growth substrate for the epitaxial structures 10 or may be bonded to the epitaxial structure 10 through a bonding layer. In some embodiment, the substrate 101 may be an insulating substrate made of sapphire (Al₂O₃) or spinel (MgAl₂O₄), or an oxide substrate made of lithium niobate, niobium gallate or a combination thereof that matches with a nitride semiconductor in terms of lattice. Alternatively, the substrate 101 may also be selected from materials such as silicon carbide SiC, ZnS, ZnO, Si, GaAs, diamond, etc. The substrate 101 includes a first surface (a1) and a second surface (a2) that is opposite to the first surface (a1). In this embodiment, the substrate 101 is a sapphire substrate.

Referring to FIG. 2, a first conductive semiconductor layer 102, an active layer 103, and a second conductive semiconductor layer 104 are sequentially stacked on the first surface (a1) of the substrate 101 to form the epitaxial structure 10 shown in FIG. 3.

The first conductive semiconductor layer 102 may be composed of group III-V or group II-VI compound semiconductors, and may be doped with a first dopant. In this embodiment, the first conductive semiconductor layer 102 may be made of a semiconductor material that is represented by Inₓ₁Al_{y1}Ga_{1-x1-y1}N, wherein 0≤x1≤1, 0≤y1≤1, and 0≤x1+y1≤1. The semiconductor material forming the first conductive semiconductor layer 102 may be selected from GaN, AlGaN, InGaN, InAlGaN, AlGaAs, GaP, GaAs, GaAsP, AlGaInP and combinations thereof. In addition, the first dopant may be an n-type dopant, such as Si, Ge, Sn, Se, or Te. When the first dopant is an n-type dopant, the first conductive semiconductor layer 102 doped with the first dopant becomes an n-type semiconductor layer. In this embodiment, the first conductive semiconductor layer 102 is an n-type semiconductor layer doped with an n-type dopant.

The active layer 103 is disposed between the first conductive semiconductor layer 102 and the second conductive semiconductor layer 104 so as to provide a region for recombination of electrons and holes to emit light. Depending on a wavelength of light that is to be emitted from the active layer 103, materials for the active layer 103 may vary. The active layer 103 may be a single quantum well or multiple quantum wells with a periodic structure. In some embodiments, the active layer 103 includes a well layer and a barrier layer, wherein the barrier layer has a bandgap that is greater than that of the well layer.

The second conductive semiconductor layer 104 is disposed on the active layer 103 and may be composed of group III-V or group II-VI compound semiconductors. The second conductive semiconductor layer 104 may be doped with a second dopant. In this embodiment, the second conductive type semiconductor layer 104 may be made of a semiconductor material that is represented by Inₓ₂Al_{y2}Ga-_{x2-y2}N, wherein, 0≤x2≤1, 0≤y2≤1, 0≤x2+y2≤1. The semiconductor materials forming the second conductive semiconductor layer 104 may be selected from AlGaAs, GaP, GaAs, GaAsP, AlGaInP and combinations thereof. When the second dopant is a p-type dopant, such as Mg, Zn, Ca, Sr, or Ba, the second conductive semiconductor layer 104 doped with the second dopant becomes a p-type semiconductor layer. In this embodiment, the second conductive semiconductor layer 104 is a p-type semiconductor layer doped with a p-type dopant.

The epitaxial structure 10 may also include other layers, such as a current spreading layer, a window layer, an ohmic contact layer, etc. The multilayer structure of the epitaxial structure 10 may have different numbers of layers according to varying doping concentrations or varying contents of components. The epitaxial structure 10 may be formed on the substrate 101 by physical vapor deposition (PVD), chemical vapor deposition (CVD), epitaxial growth technology, and atomic layer deposition (ALD), etc.

FIG. 3 shows the chip units that are formed after first and second electrodes 109, 110 are created on each of the epitaxial structures 10 by a frontend process of LED manufacturing. Each of the chip units includes the first conductive semiconductor layer 102 (i.e. the n-type semiconductor layer), the active layer 103, the second conductive semiconductor layer 104 (i.e., the p-type semiconductor layer), a current spreading layer 105, and a DBR reflection layer 106 sequentially disposed on the first surface (a1) of the substrate 101. The DBR reflective layer 106 has a first opening 107 and a second opening 108. Each of the chip units further includes the first electrode 109 disposed on the first conductive semiconductor layer 102 and the second electrode 110 disposed on the second conductive semiconductor layer 104. Specific details of methods for obtaining the epitaxial structures 10 and the first and second electrodes 109, 110 are well known to those skilled in the art, and therefore are not described herein.

Referring back to FIG. 1, in step S2, the second surface (a2) of the substrate 101 is laser processed to reduce the thickness of the substrate 101 to a target thickness (D1).

In this embodiment, the target thickness (D1) of the substrate 101 is realized by laser processing, which involves projecting a laser beam to the substrate 101 from the second surface (a2) of the substrate 101, focusing the laser beam at a certain depth, and scanning the substrate 101 horizontally back and forth so as to divide the substrate 101 into two portions. By so doing, one of the portions is removed, and the remaining portion has the reduced target thickness (D1).

In step S2, the specific depth of focus of the laser beam may be adjusted according to the target thickness (D1) of the substrate 101.

In some embodiments, the target thickness (D1) of the substrate 101 is smaller than 80 µm.

In other embodiments, the target thickness (D1) of the substrate 101 is smaller than 60 µm. In certain embodiments, the target thickness (D1) of the substrate 101 ranges from 50 µm to 60 µm.

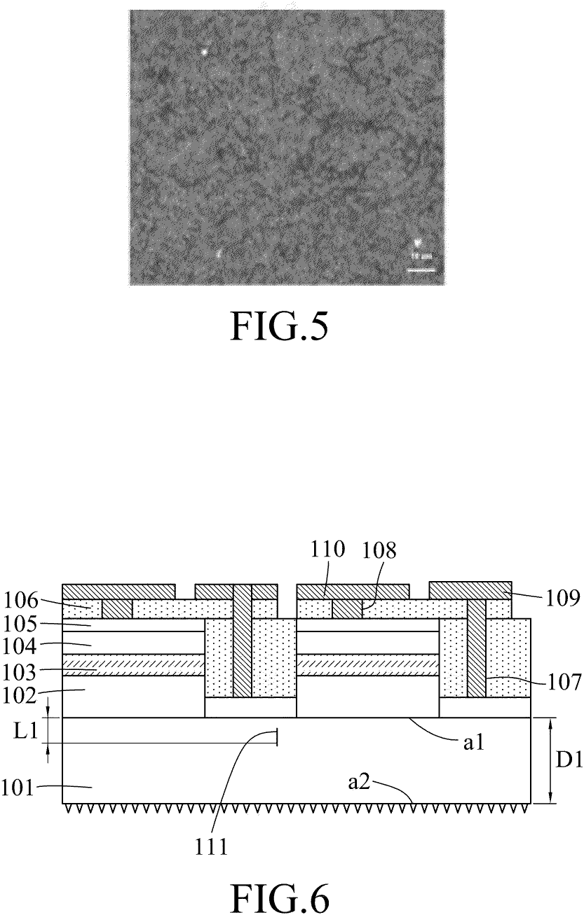

FIG. 4 shows that, after the substrate 101 is thinned by laser processing, the thickness of the substrate 101 is reduced to the target thickness (D1), and a roughened structure is formed on the second surface (a2) that is distal from the epitaxial structure 10. FIG. 5 is an AFM (Atomic Force Microscope) image of the second surface (a2) of the substrate 101 after laser processing. As shown in FIG. 5, after laser processing, the second surface (a2) of the substrate 101 has the roughened structure. In some embodiments, a surface roughness of the roughened structure ranges from 0.5 µm to 1 µm.

Since the substrate 101 is thinned by laser processing (i.e., laser cutting), which is a non-contact cutting process, the problem of wafer warpage occurring in chemical or mechanical polishing may be eliminated. Laser processing is particularly suitable for situations where the thickness of the substrate 101 needs to be smaller than 60 µm, thereby reducing the rate of breakage of wafers that are used to prepare the mini LEDs and improving production yield.

Since the second surface (a2) of the substrate 101 is a light exiting surface, roughening the second surface (a2) of the substrate 101 may enhance the light exiting efficiency of the chip units and increase the luminous intensity of the light-emitting device.

Referring back to FIG. 1, in step S3, stealth dicing is performed on the laser thinned substrate 101 to form a plurality of laser scores 111 (see FIG. 6) in the substrate 101, which are located between adjacent chip units to define a planar size of the light-emitting device to be manufactured. FIG. 6 illustrates only one of the laser scores 111 between two chip units.

In some embodiments, the laser scores 111 have a vertical distance (L1) from the first surface (a1) of the substrate 101, which is no smaller than 20 µm. With this arrangement, a majority of laser marks formed inside the substrate 101 by laser processing (i.e., laser etching) may not extend to the first surface (a1) of the substrate 101, thereby avoiding damaging the epitaxial structure 10. In some embodiments, the vertical distance (L1) from the first surface (a1) of the substrate 101 is smaller than 80 µm. In this embodiment, the location of the laser scores 111 inside the substrate 101 is the location where the laser beam is focused inside the substrate 101.

Stealth dicing refers to using a laser emitter to emit a laser pulse having a particular power, wavelength, and focal length to the substrate 101 so as to form a deteriorated layer structure at a pre-determined location inside the substrate 101, which is a loose structure having voids and pores (i.e., the laser scores 111). In step S3, when performing stealth dicing, the laser pulse enters the substrate 101 and forms the laser scores 111 in the substrate 101. The laser scores 111 form a network of longitudinal and transverse score lines, and are located between adjacent chip units to define the planar size of the light-emitting device. In this embodiment, during stealth dicing, wavelength, frequency, power, and focal length of the laser pulse are not limited, which may be adjusted according to actual requirements.

FIG. 6 is a cross-sectional schematic view showing the substrate 101 with the surface structure formed thereon after the step S3.

Referring back to FIG. 1, in step S4, the LED wafer is diced along the plurality of laser scores 111 by using a dicing tape or a dicing cutter so that a plurality of chip units are singulated.

The LED wafer of the disclosure may be diced by using an existing frontside or a backside dicing method. Specific details of the frontside and the backside dicing methods are well known to those skilled in the art, and therefore the details thereof are not to be described herein.

FIG. 7 shows a cross-sectional schematic view of a single light-emitting device obtained after step S4. The light-emitting device includes the substrate 101 and the chip unit. The chip unit has the epitaxial structure 10 and the first and second electrodes 109, 110 that are disposed on the substrate 101. In some embodiments, the target thickness (D1) of the substrate 101 is smaller than 80 µm. In other embodiments, the target thickness (D1) of the substrate 101 ranges from 50 µm to 60 µm. In certain embodiments, the light-emitting device has a planar size ranging from 3 mil*5 mil to 5 mil*9 mil.

In summary, a method of manufacturing the light-emitting device of this embodiment is provided. First, the substrate 101 is laser processed to reduce the thickness thereof to the target thickness (D1) that is smaller than 80 µm, which may resolve the problem of warpage occurred in the prior art, thereby reducing the rate of breakage of the light-emitting device and improving the production yield. After being laser processed, the second surface (a2) that is distal from the epitaxial structure 10 has a roughened structure. Since the second surface (a2) of the substrate 101 is a light exiting surface, roughening the second surface (a2) of the substrate 101 may enhance the light exiting efficiency of the chip units and increase the luminous intensity of the light-emitting device.

The method of laser processing the substrate 101 proposed by the disclosure may also be applied to a face-up light-emitting device and may be used to thin a substrate according to different thickness requirements of the substrate.

The second embodiment provides a method for manufacturing the light-emitting device, which includes the following steps.

In step S1, an LED wafer including the substrate 101 and the plurality of chip units disposed on the substrate 101 is provided.

In step S2, the second surface (a2) that is distal from the chip units (i.e., the second surface (a2) of the substrate 101) is laser processed to reduce the thickness of the substrate 101 to the target thickness (D1).

In step S3, stealth dicing is performed on the thinned substrate 101 so as to form the plurality of laser scores 111 in the substrate 101. The laser scores 111 define the planar size of the light-emitting device.

In step S4, with the laser scores 111 in the substrate 101, the LED wafer is laser cut along the laser scores 111 so that singulated light-emitting devices are obtained.

The abovementioned steps S1, S2, S3 are similar to the method in the first embodiment, wherein the substrate 101 may achieve the desired target thickness (D1) by laser processing. The difference between the first and second embodiments resides in step S4. In the first embodiment, dicing tape or dicing cutter is used to obtain the singulated light-emitting devices, whereas in the second embodiment, laser cutting is performed on the substrate 101 along the laser scores 111 on the substrate 101, such that the LED wafer is divided into the singulated light-emitting devices. In this embodiment, the thinned substrate 101 is cracked by the internal stress produced by laser cutting. Therefore, the destructive dicing tool used in the first embodiment is not required in the second embodiment.

The manufacturing method provided in the second embodiment combines laser thinning and cutting, which not only resolves the problems of wafer warpage and breakage that happen with mechanical or chemical grinding processes in the prior art, but also dispenses with the destructive dicing tool used in the first embodiment, thereby simplifying the LED manufacturing process and reduces the level of difficulty of dividing the LED wafer into small-sized light-emitting devices. This manufacturing method is particularly suitable for making ultra-thin chips.

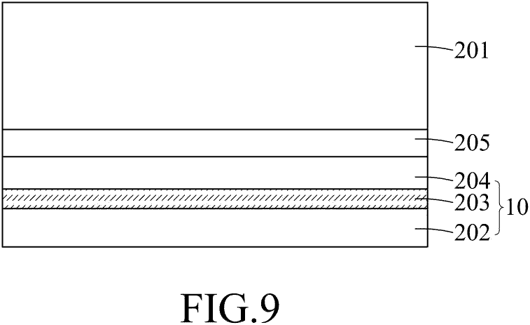

The third embodiment of the disclosure also provides a method of manufacturing the light-emitting device. The method of the third embodiment is generally similar to those of the first and second embodiments, except that the epitaxial structure 10 of the first and second embodiments is made of InAlGaN-based materials that are grown epitaxially on the first surface (a1) of the substrate 101 (e.g., a sapphire substrate), but the epitaxial structure 10 of the third embodiment is made of an AlGaInP-based material. In addition, this AlGaInP-based epitaxial structure is first formed on a gallium arsenide substrate 1 (see FIG. 8), then is transferred onto a sapphire substrate 201 (see FIG. 9).

FIG. 8 shows the gallium arsenide substrate 1 and the AlGaInP-based epitaxial structure 10 disposed thereon. The epitaxial structure 10 includes at least a first conductive semiconductor layer 202, an active layer 203, and a second conductive semiconductor layer 204 sequentially disposed on the gallium arsenide substrate 1.

FIG. 9 shows a cross-sectional schematic view of the AlGaInP-based epitaxial structure 10 bonded to the sapphire substrate 201 through a bonding layer 205, after the gallium arsenide substrate 1 is removed. The AlGaInP-based epitaxial structure 10 is bonded onto the sapphire substrate 201 using a wafer bonding method and the gallium arsenide substrate 1 is removed by grinding, polishing, etching, etc.

Then, electrodes are formed on the AlGaInP-based epitaxial structure 10 during the frontend process of LED manufacturing, and the substrate 1 is thinned using the method used in the first and second embodiments, so as to make a thickness of the substrate 1 to be smaller than 80 µm. Since the frontend process of LED manufacturing is a prior art, details thereof are not repeated herein.

Referring to FIG. 7, a fourth embodiment provides a light-emitting device, which is of a flip-chip structure, and includes the substrate 101 and a single chip unit. The substrate 101 has the first surface (a1) and the second surface (a2) opposite to the first surface (a1). The first surface (a1) of the substrate 101 has the chip unit disposed thereon, and the second surface (a2) of the substrate 101 is a light exiting surface.

The substrate 101 may be an insulating substrate or a conductive substrate. The substrate 101 may be a growth substrate for the epitaxial structure 10 and may bond the epitaxial structure 10 thereonto through a bonding layer. The substrate 101 may be an insulating substrate made of sapphire (AI₂O₃) or spinel (MgAI₂O₄), or an oxide substrate made of lithium niobate, niobium gallate or a combination thereof that matches with a nitride semiconductor in terms of lattice. Alternatively, the substrate 101 may also be selected from materials such as silicon carbide SiC, ZnS, ZnO, Si, GaAs, diamond, etc.

The chip unit includes at least the epitaxial structure 10 and electrodes disposed on the epitaxial structure 10. As shown in FIG. 2, the epitaxial structure 10 includes at least the first conductive semiconductor layer 102, the active layer 103, and the second conductive semiconductor layer 104 disposed sequentially on the first surface (a1) of the substrate 101.

The first conductive semiconductor layer 102 may be composed of group III-V or group II-VI compound semiconductors, and may be doped with a first dopant. In this embodiment, the first conductive semiconductor layer 102 may be made of a semiconductor material that is represented by Inₓ₁Al_{y1}Ga_{1-x1-y1}N, wherein 0≤x1≤1, 0≤y1≤1, and 0≤x1+y1≤1. The semiconductor material forming the first conductive semiconductor layer 102 may be selected from GaN, AlGaN, InGaN, InAlGaN, AlGaAs, GaP, GaAs, GaAsP, AlGaInP and combinations thereof. In addition, the first dopant may be an n-type dopant, such as Si, Ge, Sn, Se, or Te. When the first dopant is an n-type dopant, the first conductive semiconductor layer 102 doped with the first dopant becomes an n-type semiconductor layer. In this embodiment, the first conductive semiconductor layer 102 is an n-type semiconductor layer doped with an n-type dopant.

The active layer 103 is disposed between the first conductive semiconductor layer 102 and the second conductive semiconductor layer 104 so as to provide a region for recombination of electrons and holes to emit light. Depending on a wavelength of light that is to be emitted from the active layer 103, materials for the active layer 103 may vary. The active layer 103 may be a single quantum well or multiple quantum wells with a periodic structure. The active layer 103 includes a well layer and a barrier layer, wherein the barrier layer has a bandgap that is greater than that of the well layer.

The second conductive semiconductor layer 104 is disposed on the active layer 103 and may be composed of group III-V or group II-VI compound semiconductors. The second conductive semiconductor layer 104 may be doped with a second dopant. In this embodiment, the second conductive type semiconductor layer 104 may be made of a semiconductor material that is represented by Inₓ₂Al_{y2}Ga_{1-x2-y2}N, wherein, 0≤x2≤1, 0≤y2≤1, 0≤x2+y2≤1. The semiconductor materials forming the second conductive semiconductor layer 104 may be selected from AlGaAs, GaP, GaAs, GaAsP, AlGaInP and combinations thereof. When the second dopant is a p-type dopant, such as Mg, Zn, Ca, Sr, or Ba, the second conductive semiconductor layer 104 doped with the second dopant becomes a p-type semiconductor layer. In this embodiment, the second conductive semiconductor layer 104 is a p-type semiconductor layer doped with a p-type dopant.

The epitaxial structure 10 may also include other layers, such as a current spreading layer, a window layer, or an ohmic contact layer, etc., and may have a multilayer structure made of different quantity of layers according to doping concentration or contents of components. The epitaxial structure 10 may be formed on the substrate 101 by physical vapor deposition (PVD), chemical vapor deposition (CVD), epitaxial growth technology, and atomic layer deposition (ALD), etc.

Referring to FIG. 7, the chip unit includes at least the first conductive semiconductor layer 102, the active layer 103, the second conductive semiconductor layer 104, the current spreading layer 105, and the DBR reflection layer 106 sequentially disposed on the first surface (a1) of the substrate 101, wherein the DBR reflective layer 106 has the first opening 107 and the second opening 108. The chip unit further includes the first electrode 109 disposed on the first conductive type semiconductor layer 102, and the second electrode 110 disposed on the second conductive type semiconductor layer 104.

The target thickness (D1) of the substrate 101 is smaller than 80 µm. In some embodiments, the target thickness (D1) of the substrate 101 ranges from 50 µm to 60 µm. The planar size of the light-emitting device ranges from 3 mil*5 mil to 5 mil*9 mil. The second surface (a2) of the substrate 101 has a roughened structure formed thereon, which is formed during laser processing of the substrate 101. In some embodiments, the surface roughness of the roughened structure ranges from 0.5 µm to 1 µm. Since the second surface (a2) of the substrate 101 is a light exiting surface, the roughened structure formed on the second surface (a2) of the substrate 101 may enhance the light exiting efficiency so as to increase the luminous intensity of the light-emitting device.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a substrate that has a first surface and a second surface opposite to said first surface, said substrate having a thickness smaller than 80 µm, said second surface having a roughened structure thereon with a surface roughness ranging from 0.5 µm to 1 µm; and
a chip unit that is disposed on said first surface of said substrate.

2. The light-emitting device as claimed in claim 1, wherein said substrate has a thickness ranging from 50 µm to 60 µm.

3. The light-emitting device as claimed in claim 1, wherein said light-emitting device has a planar size ranging from 3 mil*5 mil to 5 mil*9 mil.

4. The light-emitting device as claimed in claim 1, wherein said substrate is a sapphire substrate, said chip unit being disposed on said first surface of said substrate via epitaxial growth or bonding.

5. A method for manufacturing a light-emitting device, comprising the steps of:
S1) providing an LED wafer that has a substrate and at least one chip unit, the substrate having a first surface and a second surface that is opposite to the first surface, the at least one chip unit being disposed on the first surface of the substrate; and
S2) laser processing the substrate for thinning the substrate and forming a roughened structure on the second surface of the substrate.

6. The method as claimed in claim 5, wherein in step S1, the at least one chip unit includes a plurality of chip units, and in step S2, the substrate is thinned via laser processing to reduce the thickness of the substrate to a target thickness.

7. The method as claimed in claim 6, further comprising step S3 wherein the substrate, after being thinned, is subjected to stealth dicing to form a plurality of laser scores in the substrate that define a planar size of the light-emitting device to be manufactured.

8. The method as claimed in claim 7, further comprising step S4 wherein the LED wafer is diced along the plurality of laser scores by using one of a dicing tape and a dicing cutter so that the plurality of chip units are singulated.

9. The method as claimed in claim 7, further comprising step S4 wherein the LED wafer is diced along the plurality of laser scores (111) by laser cutting so that the plurality of chip units are singulated.

10. The method as claimed in claim 6, wherein the substrate has the target thickness smaller than 80 µm.

11. The method as claimed in claim 6, wherein the substrate has the target thickness ranging from 50 µm to 60 µm.

12. The method as claimed in claim 7, wherein the plurality of laser scores have a vertical distance from the first surface of the substrate, which is smaller than the target thickness of the substrate, and 20 µm≤L1<80 µm.

13. The method as claimed in claim 5, wherein a surface roughness of the roughened structure ranges from 0.5 µm to 1 µm.
